(19) United States
(12) Patent Application Publication
(10) Pub. No.: US 2023/0249580 A1
(43) Pub. Date: Aug. 10, 2023

(54) BATTERY CONTROL APPARATUS FOR ELECTRIC VEHICLE

(71) Applicant: SUBARU CORPORATION, Tokyo (JP)

(72) Inventors: Mami OSAWA, Tokyo (JP); Kazunori KURODA, Tokyo (JP); Kenta WAKABAYASHI, Tokyo (JP); Daichi AKIYAMA, Tokyo (JP); Tatsuya ISHIBASHI, Tokyo (JP)

(21) Appl. No.: 18/150,373

(22) Filed: Jan. 5, 2023

(30) Foreign Application Priority Data
Feb. 7, 2022 (JP) 2022-016798

(51) Int. Cl. B60L 58/12; H02J 7/00; G01R 31/3835

(52) U.S. Cl. CPC B60L 58/12; H02J 7/0049; H02J 7/007182; G01R 31/3835; B60L 2250/16; B60L 2240/547

(57) ABSTRACT

A battery control apparatus for an electric vehicle includes a processor. The processor controls a charging and discharging device of the electric vehicle that includes a battery storing electric power for traveling, a power transmitter performing electric power transmission between the power transmitter and charging equipment provided outside the electric vehicle, and the charging and discharging device charging and discharging the battery via the power transmitter. The processor causes the battery to discharge to the charging equipment via the power transmitter until a voltage of the battery reaches a discharge end voltage corresponding to a state of charge (SOC) of 0%, and thereafter causes the battery to be charged until the voltage of the battery reaches a charge end voltage corresponding to the SOC of 100%. The processor creates a characteristic map representing a relation between the SOC of the battery and the voltage of the battery.

### CROSS-REFERENCE TO RELATED APPLICATIONS

The present application claims priority from Japanese Patent Application No. 2022-016798 filed on Feb. 7, 2022, the entire contents of which are hereby incorporated by reference.

### BACKGROUND

The disclosure relates to a battery control apparatus for an electric vehicle.

Japanese Unexamined Patent Application Publication No. 2020-discloses a system that calculates a degradation level of a battery of an electric vehicle while the battery is charged with external electric power.

### SUMMARY

An aspect of the disclosure provides a battery control apparatus for an electric vehicle. The battery control apparatus includes a processor. The processor is configured to control a charging and discharging device of the electric vehicle. The electric vehicle includes a battery configured to store electric power for traveling, a power transmitter configured to perform electric power transmission between the power transmitter and charging equipment provided outside the electric vehicle, and the charging and discharging device configured to charge and discharge the battery via the power transmitter. The processor is further configured to cause the battery to discharge to the charging equipment via the power transmitter until a voltage of the battery reaches a discharge end voltage corresponding to a state of charge of 0%, and thereafter cause the battery to be charged until the voltage of the battery reaches a charge end voltage corresponding to the state of charge of 100%. The processor is further configured to create a characteristic map representing a relation between the state of charge of the battery and the voltage of the battery.

### BRIEF DESCRIPTION OF THE DRAWINGS

The accompanying drawings are included to provide a further understanding of the disclosure, and are incorporated in and constitute a part of this specification. The drawings illustrate embodiments and, together with the specification, serve to explain the principles of the disclosure.

FIG. 1 is a block diagram illustrating a battery control apparatus, an electric vehicle, and charging equipment according to one example embodiment of the disclosure.

FIG. 2 is a diagram illustrating a relation between several voltage regions defined for a battery and states of charge of the battery.

FIG. 3 is a flowchart of a characteristic map creating process according to one example embodiment of the disclosure.

FIG. 4 is a timing chart illustrating a charging and discharging process according to one example embodiment of the disclosure.

FIG. 5 is a flowchart of a process of locking a power transmitter to be performed by a processor.

FIG. 6 is a part of a flowchart illustrating the characteristic map creating process according to one example embodiment of the disclosure.

FIG. 7 is a part of the flowchart illustrating the characteristic map creating process according to one example embodiment of the disclosure.

FIG. 8 is a timing chart illustrating a time period T2 in which a charging and discharging process with first accuracy is performed at Step S28 of FIG. 6.

FIG. 9 is a timing chart illustrating a time period T2 in which a charging and discharging process with second accuracy is performed at Step S37 of FIG. 7.

FIG. 10 is a timing chart illustrating a time period T2 in which a charging and discharging process with changed accuracy is performed at Step S45 of FIG. 7.

FIG. 11 is a diagram illustrating another example of the characteristic map creating process.

FIG. 12 is a diagram illustrating another example of the characteristic map creating process.

FIG. 13 a diagram illustrating another example of the characteristic map creating process.

FIG. 14 is a flowchart of an exception process to be performed by the processor in one example embodiment of the disclosure.

FIG. 15 is a timing chart illustrating an example of a part of a charging and discharging process before an exception process according to one example embodiment of the disclosure.

FIG. 16 is a timing chart illustrating an example of a part of a charging and discharging process after an exception process according to one example embodiment of the disclosure.

FIG. 17 is a system configuration diagram illustrating another arrangement example of the battery control apparatus according to one example embodiment of the disclosure.

FIG. 18 is a system configuration diagram illustrating still another arrangement example of the battery control apparatus according to one example embodiment of the disclosure.

### DETAILED DESCRIPTION

A battery of an electric vehicle varies in capacity and other characteristics with time or due to repeated charging and discharging. What is demanded of an electric vehicle that is driven by electric power supplied from the battery is to measure characteristics of the battery more accurately.

It is desirable to provide a battery control apparatus that makes it possible to measure characteristics of a battery of an electric vehicle more accurately.

In the following, some example embodiments of the disclosure are described in detail with reference to the accompanying drawings. Note that the following description is directed to illustrative examples of the disclosure and not to be construed as limiting to the disclosure. Factors including, without limitation, numerical values, shapes, materials, components, positions of the components, and how the components are coupled to each other are illustrative only and not to be construed as limiting to the disclosure. Further, elements in the following example embodiments which are not recited in a most-generic independent claim of the disclosure are optional and may be provided as needed. The drawings are schematic and are not intended to be drawn to scale.

Throughout the present specification and the drawings, elements having substantially the same function and configuration are denoted with the same reference numerals to avoid any redundant description. In addition, elements that are not directly related to any embodiment of the disclosure are unillustrated in the drawings.

### First Example Embodiment

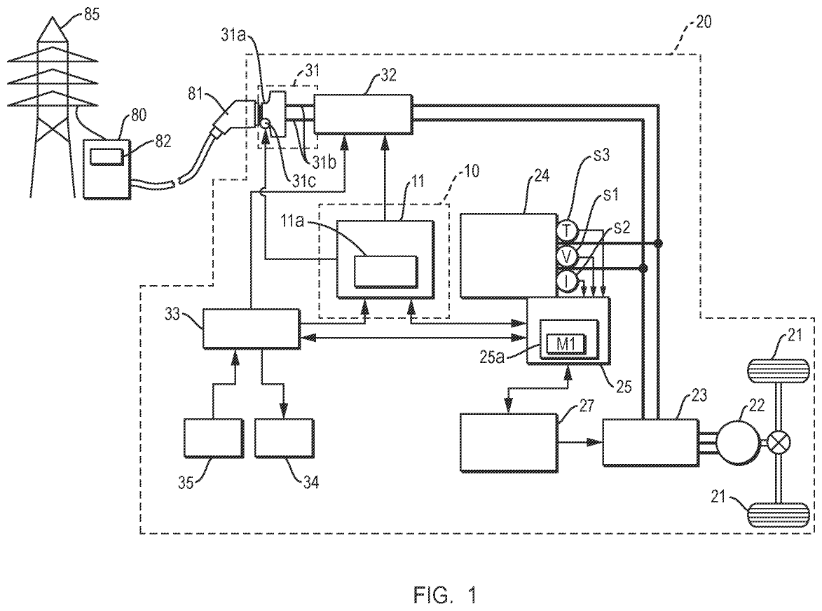

FIG. 1 is a block diagram illustrating a battery control apparatus 10, an electric vehicle 20, and charging equipment 80 according to a first example embodiment of the disclosure. The battery control apparatus 10 of the first example embodiment is applicable to the electric vehicle 20 and controls charging of a battery 24 of the electric vehicle 20.

The electric vehicle 20 may include drive wheels 21, an electric motor 22, the battery 24, an inverter 23, a vehicle control unit 27, and a battery control unit 25. The electric motor 22 may output driving force to the drive wheels 21. The battery 24 may supply electric driving power to the electric motor 22. The inverter 23 may cause the electric motor 22 to perform power running or regenerative running. The vehicle control unit 27 may control the inverter 23 so that driving force or regenerative braking force is generated in accordance with a driving operation and a vehicle state. The battery control unit 25 may manage the battery 24. The electric vehicle 20 may further include a power transmitter 31, a charging and discharging device 32, a charging management unit 33, a display unit 34, and an input unit 35. The power transmitter 31 performs electric power transmission between the battery 24 and the charging equipment 80 provided outside the electric vehicle 20. The charging and discharging device 32 may be an in-vehicle charger that charges and discharges the battery 24 via the power transmitter 31. The charging management unit 33 may manage a charging schedule via the charging and discharging device 32. The display unit 34 may output information to an occupant of the electric vehicle 20. The input unit 35 may receive information inputted by the occupant.

The battery 24 may be, for example, a lithium-ion secondary battery or a nickel-hydrogen secondary battery. The battery 24 may be a storage battery whose characteristics vary with time or depending on the number of times of charging and discharging. The battery 24 may be any kind of a storage battery that stores electric power to drive the electric motor 22. The battery 24 may be provided with a voltmeter s1, an ammeter s2, and a thermometer s3, and measurement values acquired by the voltmeter s1, the ammeter s2, and the thermometer s3 may be sent to the battery control unit 25.

The battery control unit 25 may manage a state of the battery 24 and determine whether a request for discharging or regenerative charging received from the vehicle control unit 27 is acceptable. The battery control unit 25 may include a memory 25a. The memory 25a may store a characteristic map M1 representing a relation between an open circuit voltage (OCV) of the battery 24 and a state of charge (SOC) of the battery 24. The battery control unit 25 may calculate the SOC of the battery 24 from the OCV of the battery 24 referring to the characteristic map M1.

The power transmitter 31 may include a connector 31a to which a charging plug 81 of the charging equipment 80 is to be coupled, and a power line 31b through which electric power is sent from the connector 31a to the charging and discharging device 32. The power transmitter 31 may include a lock mechanism 31c. When the power transmitter 31 is coupled to the charging equipment 80 to perform electric power transmission between the battery 24 and the charging equipment 80, the lock mechanism 31c may lock the coupling state. The lock mechanism 31c may be switched between a locked state and an unlocked state under control of a processor 11 of the battery control apparatus 10.

The power transmitter 31 is not limited to the configuration described above. For example, the power transmitter 31 may have a configuration allowing for non-contact electric power transmission. For example, the power transmitter 31 may include a power transmitting coil and a power line that transmits electric power from the power transmitting coil to the charging and discharging device 32. In this case, the charging equipment 80 may include a power transmitting coil disposed on the ground, and may perform non-contact electric power transmission via the power transmitting coil.

The charging and discharging device 32 may include a power conversion circuit that achieves voltage conversion and current control. The power conversion circuit may transmit a charging current to the battery 24 via the power transmitter 31 and receive a discharging current from the battery 24. The charging and discharging device 32 may perform a charging operation or a discharging operation in accordance with a command from the charging management unit 33 or the processor 11 of the battery control apparatus 10.

When a user sets timer charging, the charging management unit 33 may receive data on a charging schedule from the user via the input unit 35. The data on the charging schedule may include a charging completion time and a charging amount, for example. The charging management unit 33 may manage the charging schedule on the basis of the data on the charging schedule. The charging management unit 33 may receive SOC information regarding the battery 24 from the battery control unit 25 and output the SOC information to the display unit 34.

The charging equipment 80 is configured to supply and receive electric power. The charging equipment 80 may include a meter 82 that totalizes and measures supplied electric power and received electric power to manage the amount of electric power supplied from the charging equipment 80 to the electric vehicle 20 and the amount of electric power sent from the electric vehicle 20 to the charging equipment 80. Electric power to be supplied from the charging equipment 80 to the electric vehicle 20 may be purchased by the user from an electric power company, and electric power to be sent from the electric vehicle 20 to the charging equipment 80 may be sold from the user to an electric power company. The electric power sent from the electric vehicle 20 to the charging equipment 80 may be returned to an electric power system 85, which prevents the electric power from being wasted. The charging equipment 80 may temporarily store electric power received from the electric vehicle 20. The charging equipment 80 may be disposed on the ground, and in this case, called grounded equipment.

The battery control apparatus 10 includes the processor 11 and may perform a process of updating the characteristic map M1. The processor 11 may include one electronic control unit (ECU) or two or more ECUs operable in cooperation with each other via communication. The processor 11 may send a command to the charging and discharging device 32 to thereby control charging and discharging of the battery 24 via the power transmitter 31. When creating a new characteristic map M1, the processor 11 may send the new characteristic map M1 to the battery control unit 25 to update the previous characteristic map M1 stored in the memory 25a. The processor 11 may communicate with the battery control unit 25 to thereby acquire a voltage and a current of the battery 24. Alternatively, the processor 11 may acquire a voltage and a current of the battery 24 from the charging and discharging device 32.

The processor 11 may include a memory 11a that holds a program for a control process in which a characteristic map is created (hereinafter referred to as a characteristic map creating process or a control process).

<Practical SOC and Actual SOC>

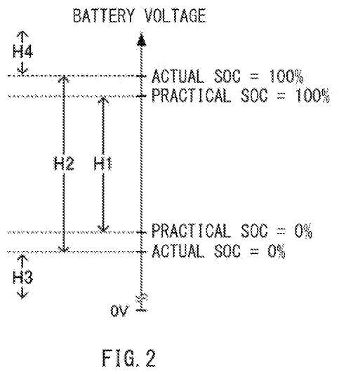

FIG. 2 illustrates several voltage ranges defined for the battery 24 and states of charges (SOCs) of the battery 24.

The battery 24 may have four voltage regions H1 to H4. The voltage region H1 may be a region in which charging and discharging is achieved on the basis of practical charging and discharging specifications with less degradation of the battery 24. The voltage region H2 may be a region in which charging and discharging is achieved on the basis of charging and discharging specifications for battery characteristic measurement with less degradation of the battery 24. The voltage regions H3 may be an overdischarge region in which degradation of the battery 24 can proceed. The voltage regions H4 may be an overcharge region in which degradation of the battery 24 can proceed. The charging management unit 33 and the battery control unit 25 may perform control to cause the battery 24 to be charged or discharged in the voltage region H1. Thus, the charging management unit 33 and the battery control unit 25 may define the SOC as 100% when the voltage of the battery 24 reaches an upper limit voltage of the voltage region H1, while as 0% when the voltage of the battery 24 reaches a lower limit voltage of the voltage region H1. The SOC defined on the basis of the voltage region H1 is hereinafter referred to as a practical SOC.

The charging management unit 33 may use the practical SOC as a SOC to be displayed to the occupant.

In order to create an accurate characteristic map M1, the battery control apparatus 10 may perform charging and discharging of the battery 24 in the voltage region H2, which is larger than the practical voltage region H1. Thus, the battery control apparatus 10 may define the SOC as 100% when the voltage of the battery 24 reaches an upper limit voltage of the voltage region H2, while as 0% when the voltage of the battery 24 reaches a lower limit voltage of the voltage region H2 in addition to the definition of the practical SOC. The SOC defined on the basis of the voltage region H2 is hereinafter referred to as an actual SOC.

<Characteristic Map Creating Process>

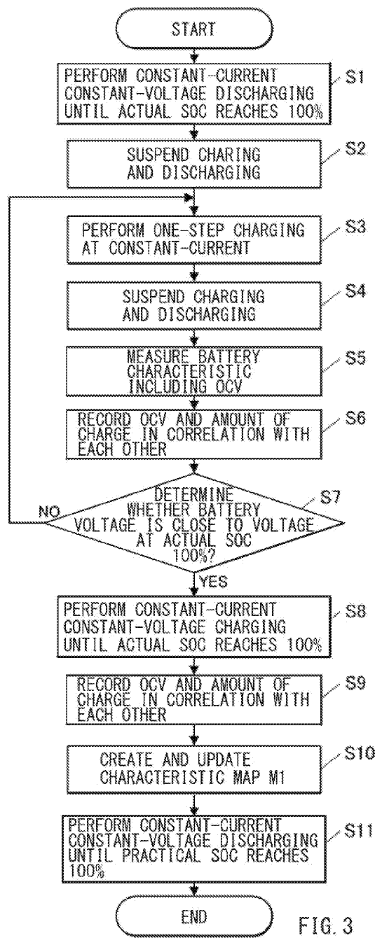

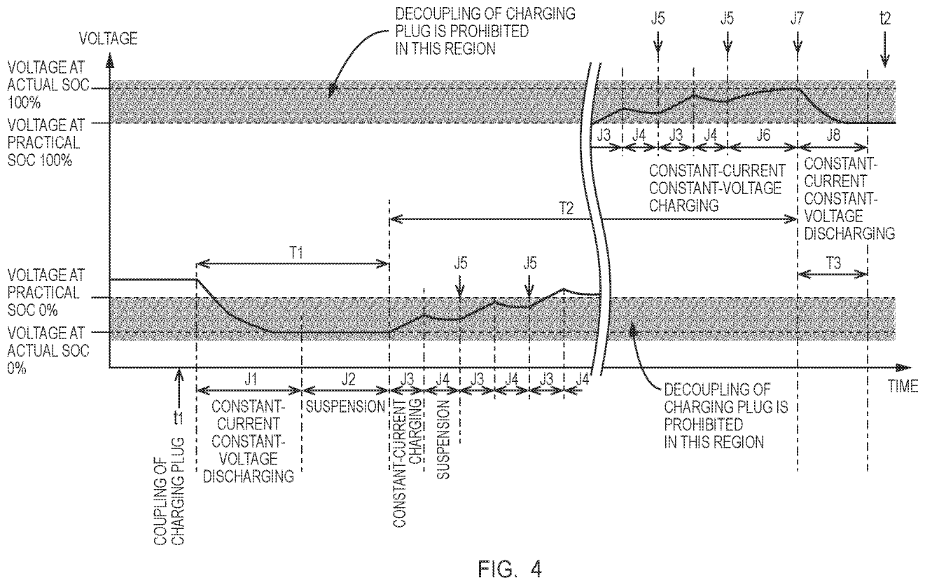

FIG. 3 is a flowchart of a characteristic map creating process according to the first example embodiment. FIG. 4 is a timing chart illustrating a charging and discharging process according to the first example embodiment.

The processor 11 may execute the characteristic map creating process when receiving a request to update the characteristic map M1. The processor 11 itself may issue the update request depending on usage of the battery 24, such as an elapse of a predetermined time, the number of times of charging and discharging greater than or equal to a predetermined number of times. Alternatively, a user or a maintenance personnel may input the update request. In a case where the update request has been issued and where the charging schedule with sufficiently enough time to create the characteristic map M1 has been set by the charging management unit 33, or in a case where creation of the characteristic map M1 is permitted by the user, the processor 11 may execute the characteristic map creating process together with a charging process following the charging schedule of the battery 24.

The characteristic map creating process may start in a condition where the power transmitter 31 and the charging equipment 80 are coupled to each other so that electric power transmission is available between the power transmitter 31 and the charging equipment 80. When the characteristic map creating process starts, the processor 11 may cause the charging and discharging device 32 to perform constant-current constant-voltage discharging of the battery 24 so that the actual SOC reaches 0% (Step S1). That is, the battery 24 may be discharged at a constant current until the battery 24 reaches a voltage at the actual SOC of 0%, and thereafter discharged at the voltage until a discharge current reaches a predetermined low level.

Thereafter, the processor 11 may suspend charging and discharging of the battery 24 for a predetermined time to eliminate polarization of the battery 24 (Step S2).

In the timing chart illustrated in FIG. 4, a timing t1 indicates coupling of the power transmitter 31 to the charging equipment 80. In FIG. 4, the constant-current and constant-voltage discharging in Step S1 and the suspension of charging and discharging in Step S2 are represented as J1 and J2, respectively. In a time period T1, the voltage of the battery 24 may decrease to the voltage at the actual SOC of 0%, and polarization of the battery 24 is eliminated.

Thereafter, the processor 11 may repeat a procedure including Steps S3 to S6 until the voltage of the battery 24 increases to a voltage close to the actual SOC of 100% (e.g., a voltage of 95%). In such a repetitive procedure, first, the processor 11 may cause the charging and discharging device 32 to perform one-step charging (Step S3). The one-step charging may be constant current charging by a predetermined amount (e.g., several percent of the actual SOC). Thereafter, the processor 11 may suspend charging and discharging of the battery 24 to eliminate the polarization of the battery 24 (Step S4). The suspension may take a predetermined time. Thereafter, the processor 11 may measure a characteristic of the battery 24 (Step S5). The characteristic to be measured may be an OCV. Thereafter, the processor 11 may record the measured OCV and a corresponding amount of charge that are correlated with each other (Step S6). Thereafter, in Step S7, the processor 11 may determine whether the voltage of the battery 24 is close to a voltage at the actual SOC of 100% (e.g., a voltage of 95% or greater of the present actual SOC). If the voltage of the battery 24 is not close to the voltage at the actual SOC of 100% (Step S7: NO), the processor 11 may return the process to Step S3.

In contrast, if the voltage of the battery 24 is close to the voltage at the actual SOC of 100% (Step S7: YES), the processor 11 may cause the charging and discharging device 32 to perform constant-current constant-voltage charging so that the voltage of the battery 24 reaches the voltage at the actual SOC of 100% (Step S8). For example, first, the processor 11 may charge the battery 24 at a constant current until the battery 24 reaches the voltage at the actual SOC of 100%, and thereafter charge the battery 24 at the voltage until a charging current reaches a predetermined low level. When the constant-current constant-voltage charging is completed, the processor 11 may record the OCV and the amount of charge at the time of the completion of the constant-current constant-voltage charging in correlation with each other (Step S9).

In the timing chart illustrated in FIG. 4, the repetitive procedure including Steps S3 to S6 is represented as processes J3 to J5 in a time period T2. Steps S8 and S9 are represented as processes J6 and J7, respectively. In the time period T2, the amount of charge may vary through multiple steps from the voltage at the actual SOC of 0% to the voltage at the actual SOC of 100%, and the OCV and the amount of charge in each step may be recorded in correlation with each other.

Thereafter, the processor 11 may create the characteristic map M1 on the basis of the OCVs and the amounts of charge recorded in Steps S6 and S9 (Step S10). For example, first, the processor 11 may calculate a curve representing the relation between the OCV and the amount of charge on the basis of the records described above. Thereafter, the processor 11 may convert the value of the amount of charge into the practical SOC assuming that the amount of charge is 0% when a voltage at the practical SOC is 0%, and the amount of charge is 100% when a voltage at the practical SOC is 100% in this curve. Thereafter, the processor 11 may create the characteristic map M1 of the SOC (i.e., the practical SOC) on the basis of the curve generated as a result of the conversion. Thereafter, the processor 11 may send the characteristic map M1 to the battery control unit 25 (Step S10) to thereby update the previous characteristic map M1.

After the characteristic map M1 is updated, the processor 11 may cause the charging and discharging device 32 to perform constant-current constant-voltage discharging so that the voltage of the battery 24 reaches the voltage at the practical SOC of 100% (Step S11). Thereafter, the processor 11 may end the characteristic map creating process. Alternatively, the processor 11 may perform Steps S9 and S10 or the characteristic map creating process after the constant-current constant-voltage discharging at Step S11.

In the timing chart illustrated in FIG. 4, Step S11 is represented as a process J8 in a time period T3. A timing t2 indicates completion of charging of the battery 24. In the time period T3, the voltage of the battery 24 may be decreased to the voltage at the practical SOC of 100%, following which the battery control unit 25 may manage charging and discharging of the battery 24 within the voltage region H1 from the practical SOC of 0% to the practical SOC 100% (see FIG. 2). Thereafter, the vehicle control unit 27 may cause the electric motor 22 to perform power running or regenerative running using the battery 24 within the voltage region H1 from the practical SOC of 0% to the practical SOC of 100% (see FIG. 2).

<Lock Process of Power Transmitter>

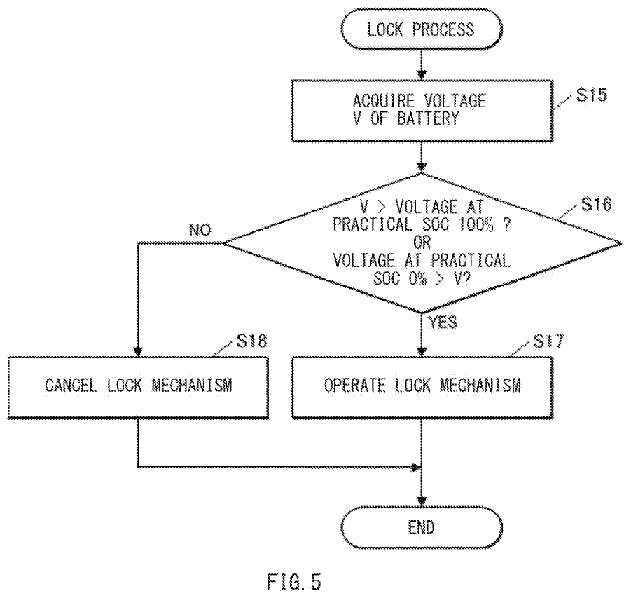

FIG. 5 is a flowchart of a process of locking the power transmitter 31 (hereinafter referred to as a lock process) to be performed by the processor 11. The processor 11 may perform the lock process of the power transmitter 31 in parallel to the characteristic map creating process described above (see FIG. 3). In the lock process, the processor 11 may acquire a voltage V of the battery 24 (Step S15), and may determine whether the voltage V is less than the voltage at the practical SOC of 0% or whether the voltage V is greater than the voltage at the practical SOC of 100% (Step S16). If the result of the determination in Step S16 is YES (Step S16: YES), the processor 11 may cause the lock mechanism 31c to operate to prevent decoupling of the power transmitter 31 (Step S17). In contrast, if the result of the determination in Step S16 is NO (Step S16: NO), the processor 11 may cancel the lock mechanism 31c (Step S18). The processor 11 may repeat the procedure including Steps S15 to S18 at a predetermined control timing while the characteristic map creating process is executed.

Shaded regions in FIG. 4 are outside the voltage region H1 in which charging and discharging is achieved on the basis of the practical charging and discharging specifications with less degradation of the battery 24. Thus, it may be unpreferable to perform charging and discharging associated with traveling of the electric vehicle 20 within the shaded regions. Accordingly, when the voltage of the battery 24 is within any of the shaded regions illustrated in FIG. 4, the lock process illustrated in FIG. 5 may be performed to prevent the power transmitter 31 and the charging equipment 80 from decoupling from each other. Note that a measure to prevent the decoupling is not limited to the operation of the lock mechanism 31c. For example, the decoupling may be prevented by outputting a notification from the processor 11 to warn the decoupling.

A program for the characteristic map creating process (FIG. 3) or a program for the lock process of the power transmitter 31(FIG. 5) may be stored in a non-transitory computer readable medium such as the memory 11a is of the processor 11. Alternatively, the processor 11 may read a program from a portable non-transitory computer readable medium and execute the program. The portable non-transitory computer readable medium may store the program for the characteristic map creating process or the program for the lock process of the power transmitter 31 described above.

According to the battery control apparatus 10 of the first example embodiment described above, the processor 11 causes the battery 24 to discharge to the charging equipment 80 until the voltage of the battery 24 reaches the voltage at the actual SOC of 0% (i.e., a discharge end voltage), and thereafter causes the battery 24 to be charged until the voltage of the battery 24 reaches the voltage at the actual SOC of 100% (i.e., a charge end voltage). During such a process, the processor 11 records the amount of electric power charged in the battery 24 and the OCV, and creates an accurate characteristic map M1 on the basis of the record.

The electric power discharged from the battery 24 to the charging equipment 80 may be received by the charging equipment 80, which prevents the electric power from being wasted. Accordingly, it is possible to create the characteristic map M1 without contradicting eco-friendly, energy-saving guidelines. Further, unlike in the case of waste discharging, it is possible to reduce a loss for the user.

Further, according to the battery control apparatus 10 of the first example embodiment, the two states of charge, i.e., the practical SOC and the actual SOC may be defined. The processor 11 may vary the SOC of the battery 24 from the voltage at the actual SOC of 0% to the voltage at the actual SOC of 100% on the basis of the actual SOC to thereby create the characteristic map M1. Such a characteristic map creating process allows for accurate measurement of the OCV in the vicinity of the practical SOC of 0% and the OCV in the vicinity of the practical SOC of 100% within the practical SOC range that is narrower than the actual SOC range. Accordingly, it is possible to obtain an accurate characteristic map M1 of the battery 24 to be used in the practical SOC range.

In the foregoing example embodiment, the processor 11 may acquire the data for creating the characteristic map M1 on the basis of the actual SOC. However, the processor 11 may acquire the data for creating the characteristic map M1 on the basis of the practical SOC. For example, the processor 11 may charge the battery 24 from the voltage at the practical SOC of 0% (i.e., a discharge end voltage) to the voltage at the practical SOC of 100% (i.e., a charge end voltage) to thereby acquire the data for creating the characteristic map M1, without performing the charging and discharging between the actual SOC of 0% and the practical SOC of 0% and the charging and discharging between the practical SOC of 100% and the actual SOC of 100%.

According to the battery control apparatus 10 of the first example embodiment, the battery 24 may be charged until the battery 24 reaches the actual SOC of 100%, and thereafter discharged to the charging equipment 80 until the battery 24 reaches the practical SOC of 100%. Such a process makes it possible to create the characteristic map M1 and thereafter use the battery 24 within the practical SOC range from 0% to 100%. Accordingly, it is possible to suppress degradation of the battery 24 even if the battery 24 is used on the basis of the practical charging and discharging specifications after the characteristic map M1 is created.

Further, according to the battery control apparatus 10 of the first example embodiment, at least in a case where the voltage of the battery 24 becomes less than the voltage at the practical SOC of 0% or greater than the voltage at the practical SOC of 100% while the characteristic map creating process is executed, the processor 11 may prevent the power transmitter 31 and the charging equipment 80 from decoupling from each other. This helps to prevent the battery 24 from being used to cause the electric vehicle 20 to travel in a condition where the voltage of the battery 24 is outside the practical SOC range from 0% to 100%. Accordingly, it is possible to suppress degradation of the battery 24. Instead of controlling the lock mechanism 31c of the power transmitter 31, the processor 11 may perform a warning process in which a warning display or sound is outputted to the user to prevent the user from decoupling the power transmitter 31.

### Second Example Embodiment

The battery control apparatus 10 according to a second example embodiment may have a configuration similar to that of the first example embodiment except that a characteristic map creating process according to the second example embodiment is partly different from the characteristic map creating process according to the first example embodiment.

As described above, the amount of charge and voltage of the battery 24 may increase through the multiple steps in the time period T2 (see FIG. 4) of the characteristic map creating process. Further, the amount of charge and the OCV may be recorded in correlation with each other once in each of the multiple steps. Hereinafter, an interval between every two adjacent steps of the multiple steps may be referred to as a step interval. The paired data on the amount of charge and the OCV recorded in correlation with each other in each step may correspond to one plot on a charging amount-OCV coordinate, and may thus be hereinafter referred to as a plot.

In the characteristic map creating process, charging and discharging may be suspended after every one-step charging to eliminate polarization. Thus, in a case where the step interval is shortened by reducing the amount of charge in every one-step charging, a large number of plots are obtained at a short interval, whereas the total processing time becomes longer accordingly. In contrast, in a case where the step interval is elongated by increasing the amount of charge in every one-step charging, plots are accordingly acquired at a long interval, which results in a decrease in resolution performance and in turn, a decrease in accuracy of the characteristic map M1. To address such an issue, the battery control apparatus 10 according to the second example embodiment may vary the step interval depending on a situation to thereby achieve the characteristic map creating process appropriate to the situation.

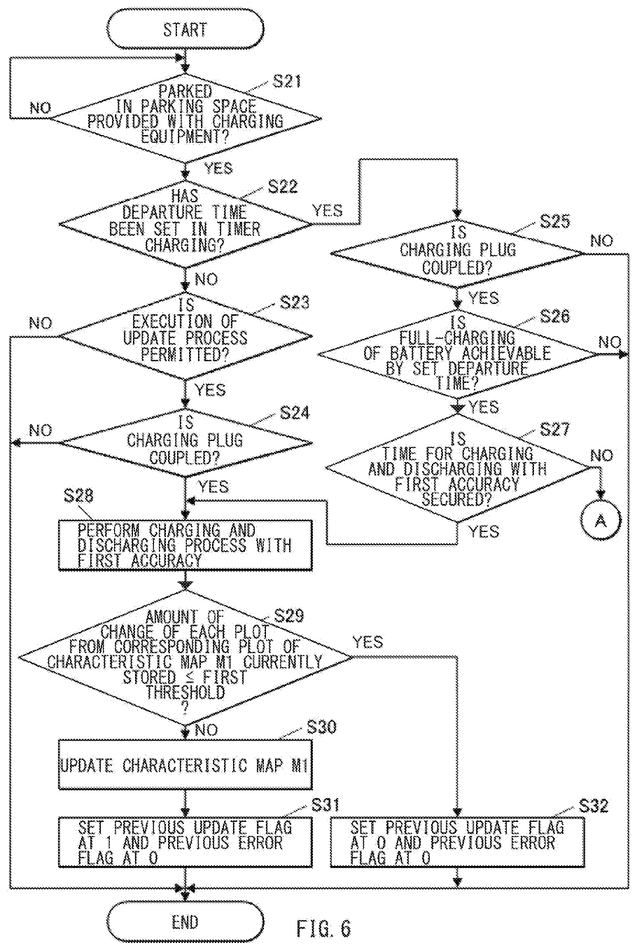

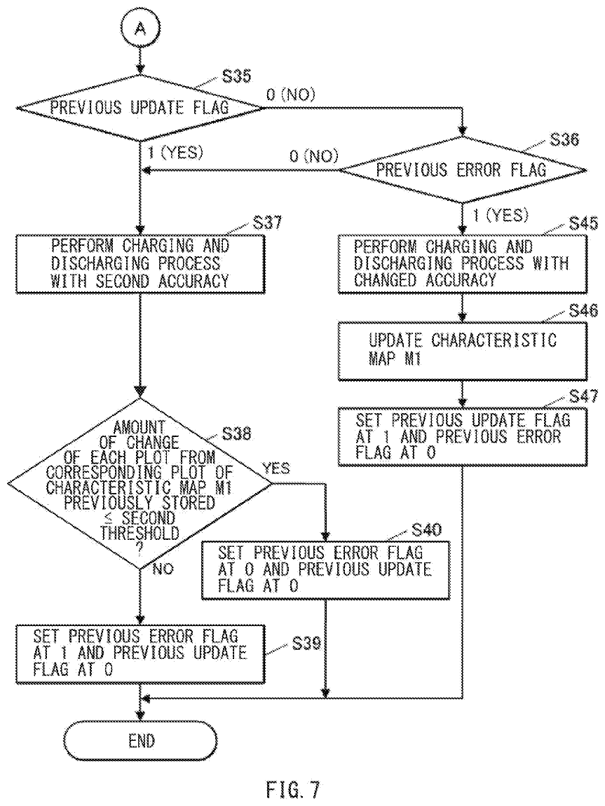

FIGS. 6 and 7 are flowcharts illustrating the characteristic map creating process according to the second example embodiment.

In the characteristic map creating process, the processor 11 may determine whether the electric vehicle 20 is parked in a parking space provided with the charging equipment 80 (Step S21). If the electric vehicle 20 is parked in a parking space provided with the charging equipment 80 (Step S21: YES), the processor 11 may cause the process to proceed to Step S22. Location information on the parking space may be preliminarily stored in the processor 11 or the charging management unit 33. The processor 11 may perform the determination at Step S21 by comparing position information on the electric vehicle 20 with the location information on the parking space.

In Step S22, the processor 11 may determine whether a departure time (a charging completion time) has been set in the timer charging.

If the departure time has not been set in the timer charging (Step S22: NO), the processor 11 may cause the charging management unit 33 to inquire whether the user permits execution of the update process of the characteristic map M1 (Step S23). Alternatively, the processor 11 may determine whether the permission has been received from the user. The charging management unit 33 may receive information regarding whether the update process of the characteristic map M1 is permitted together with the data on the charging schedule received from the user.

If the execution of the update process of the characteristic map M1 is not permitted (Step S23: NO), the processor 11 may end the characteristic map creating process. Thereafter, the processor 11 may start the process from Step S1 again after a predetermined control cycle.

In contrast, if the update process of the characteristic map M1 is permitted (Step S23: YES), the processor 11 may determine whether the charging and discharging device 32 is coupled to the charging equipment 80 (i.e., whether the charging plug 81 is coupled to the connector 31a) (Step S24).

If the charging and discharging device 32 is not coupled to the charging equipment 80 (Step S24: NO), the processor 11 may end the characteristic map creating process. In contrast, if the charging and discharging device 32 is coupled to the charging equipment 80 (Step S24: YES), the processor 11 may execute a charging and discharging process with first accuracy (Step S28).

If the departure time has been set in the timer charging in Step S22 (Step S22: YES), the processor 11 may determine whether the charging and discharging device 32 is coupled to the charging equipment 80 (i.e., the charging plug 81 is coupled to the connector 31a) (Step S25). If the charging and discharging device 32 is not coupled to the charging equipment 80 (Step S25: NO), the processor 11 may end the characteristic map creating process.

If the charging and discharging device 32 is coupled to the charging equipment 80 (Step S25: YES), the processor 11 may determine whether full-charging of the battery 24 is achievable by the departure time set in the timer charging (Step S26). If full-charging of the battery 24 is not achievable by the departure time (Step S26: NO), the processor 11 may end the characteristic map creating process.

In contrast, if full-charging of the battery 24 is achievable by the departure time (Step S26: YES), the processor 11 may determine whether time for the charging and discharging process with the first accuracy, which is to be performed in Step S28, is able to be secured (Step S27). If the time is able to be secured (Step S27: YES), the processor 11 may perform the charging and discharging process with the first accuracy (Step S28).

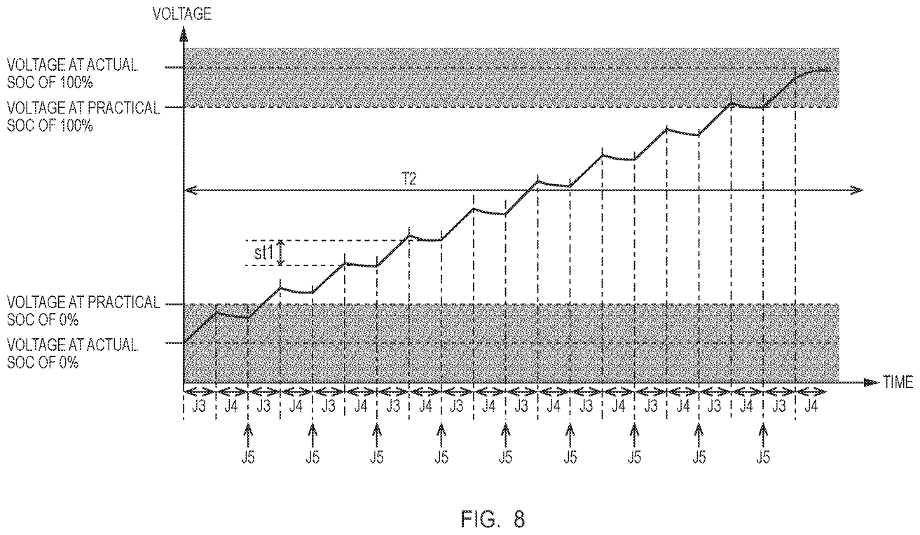

FIG. 8 is a timing chart illustrating a part of the charging and discharging process with the first accuracy. The charging and discharging process with the first accuracy in Step S28 may correspond to the charging and discharging processes in the time periods T1 to T3 described in the first example embodiment with reference to FIG. 4. In FIG. 8, only the charging process in the time period T2 in FIG. 4 is illustrated. The charging and discharging process with the first accuracy may be performed at a predetermined short step interval st1 as in the timing chart illustrated in FIG. 8. Each predetermined short step interval st1 may be set to 10% of the practical SOC, for example. Thus, a large number of plots (ten plots, for example) may be recorded. Although the charging and discharging process with the first accuracy takes a long time, the characteristic map M1 with high accuracy is obtainable through the charging and discharging process with the first accuracy.

When the charging and discharging process with the first accuracy is completed in Step S28, the processor 11 may determine for each of all the acquired plots whether the amount of change from corresponding one of the plots of the characteristic map M1 currently stored in the battery control unit 25 is less than or equal to a first threshold (Step S29). The amount of change may indicate an error of the current characteristic map M1 (i.e., a deviation from a true value). In one example, the processor 11 may calculate a difference between each of the acquired plots and corresponding one of the plots of the characteristic map M1, and may define the maximum value among the differences as the amount of change. Alternatively, the processor 11 may calculate a difference between each of all of the acquired plots and corresponding one of the plots of the characteristic map M1, and may define a root-sum-square value of the differences as the amount of change. The difference between one of the acquired plots and corresponding one of the plots of the characteristic map M1 may be calculated as follows:

Difference=|(amount of charge indicated by plot)−(amount of charge corresponding to SOC acquired by applying OCV indicated by plot to characteristic map M1)|.

The first threshold to be used in Step S29 may be set to a threshold amount of change for determining whether the characteristic map M1 is to be updated.

If the amount of change is greater than the first threshold (Step S29: NO), the processor 11 may send a newly created characteristic map M1 to the battery control unit 25 to update the previous characteristic map M1 (Step S30). Thereafter, the processor 11 may set a previous update flag at “1”, and a previous error flag to “0” (Step S31). Thereafter, the processor 11 may end the characteristic map creating process. The value of each flag may be continuously used in the next characteristic map creating process.

In contrast, if the amount of change is less than or equal to the first threshold (Step S29: YES), the processor 11 may set the previous update flag at “0” and the previous error flag at “0” without updating the characteristic map M1 (Step S32). Thereafter, the processor 11 may end the characteristic map creating process. The value of each flag may be continuously used in the next characteristic map creating process.

The previous update flag may be a flag indicating whether the characteristic map M1 has been updated in the previous characteristic map creating process.

If it is determined in Step S27 that the time is not able to be secured (Step S27: NO), the processor 11 may determine the value of the previous update flag (Step S35). If the previous update flag is “1” (Step S35: YES), the processor 11 may execute a charging and discharging process with second accuracy (Step S37).

If it is determined in Step S35 that the previous update flag is “0” (Step S35: NO), the processor 11 may determine the value of the previous error flag (Step S36). If the previous error flag is “0” (Step S36: NO), the processor 11 may execute the charging and discharging process with the second accuracy (Step S37).

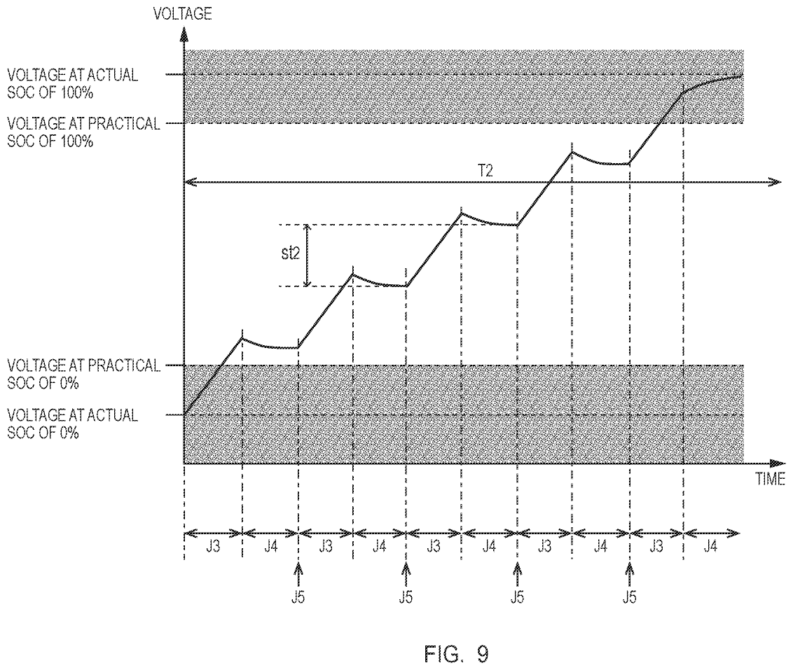

FIG. 9 is a timing chart illustrating a part of the charging and discharging process with the second accuracy. The charging and discharging process with the second accuracy may be similar to the charging and discharging processes in the time periods T1 to T3 illustrated in FIG. 4 except that the process in the time period T2 is changed to a process illustrated in FIG. 9. The charging and discharging process with the second accuracy may be performed at a long step interval st2. The long step interval st2 may be longer than the short step interval st1 in the charging and discharging process with the first accuracy. Thus, a small number of plots may be acquired in the charging and discharging process with the second accuracy. If the characteristic map M1 is created on the basis of only the small number of plots, the accuracy of the characteristic map M1 can decrease.

Before starting the charging and discharging process with the second accuracy, the processor 11 may set the step interval st2 to an interval as short as possible within the time secured for the charging and discharging process with the second accuracy, and may execute the charging and discharging process with the second accuracy at the step interval st2 (Step S37). In the charging and discharging process illustrated in FIG. 9, each step interval st2 may be set to 20% of the practical SOC, and thus five plots may be recorded.

When the charging and discharging process with the second accuracy is completed, the processor 11 may calculate the amount of change in each of all the acquired plots from corresponding one of the plots of the characteristic map M1 currently stored in the battery control unit 25, and may determine whether each of the amounts of change is less than or equal to a second threshold (Step S38). The amount of change may indicate an error of the current characteristic map M1 (i.e., a deviation from a true value). For example, if the amounts of change of one or more of the acquired plots are greater than the second threshold, it may be determined in Step S38 as “NO”.

The second threshold may be set at a threshold amount of change for determining whether the characteristic map M1 is to be updated.

If it is determined in Step S38 that the amount of change is greater than the second threshold (Step S38: NO), the processor 11 may set the previous error flag at “1”, and the previous update flag at “0” (Step S39). If it is determined in Step S38 that the amount of change is less than or equal to the second threshold (Step S38: YES), the processor 11 may set the previous error flag at “0”, and the previous update flag at “0” (Step S40). Thereafter, the processor 11 may end the characteristic map creating process. The value of each flag and the amount of change of each of all the plots calculated in Step S38 may be continuously used in the next characteristic map creating process.

The previous error flag may indicate whether a plot of which amount of change is large is included in the small number of plots acquired in the previous characteristic map creating process.

If it is determined in Step S35 that the previous update flag is “0” (Step S35: NO), and if it is determined in Step S36 that the previous error is “1” (Step S35: YES), the processor 11 may execute a charging and discharging process with changed accuracy (Step S45).

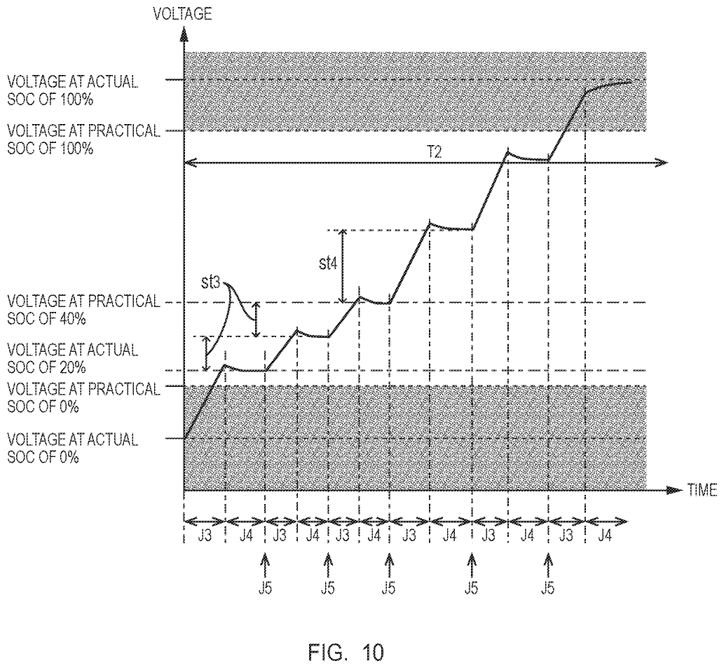

FIG. 10 is a timing chart illustrating a part of the charging and discharging process with the changed accuracy. The charging and discharging process with the changed accuracy may similar to the charging and discharging processes in the time periods T1 to T3 illustrated in FIG. 4 except that the process in the time period T2 is changed to a process illustrated in FIG. 10. In the charging and discharging process with the changed accuracy, charging and discharging may be performed at a short step interval in one voltage range, and charging and discharging may be performed at a long step interval in another voltage range. The voltage range in which the step interval is short may be defined in the vicinity of a voltage corresponding to the plot at which the error of the characteristic map M1 (i.e., the amount of change of the acquired plot from corresponding one of the plots of the characteristic map M1) was determined to be greater than the second threshold in the previous control process. In the example illustrated in FIG. 10, the amount of change may become greater than the second threshold at a plot in the vicinity of the actual SOC of 30%, and a short step interval st3 may be applied to a peripheral voltage range from the actual SOC of 20% to 40%, while a large step interval st4 may be applied to the other voltage range.

Through the charging and discharging process with the changed accuracy, a large number of plots may be acquired within the voltage range to which the short step interval is applied. For example, multiple plots may be acquired at a short interval within the voltage range around the plot at which the amount of change was greater than the second threshold in the previous charging and discharging process with the second accuracy (Step S37).

After executing the charging and discharging process with the changed accuracy in Step S45, the processor 11 may create a new characteristic map M1 on the basis of the multiple plots acquired in the above-described process, and may update the characteristic map M1 stored in the battery control unit 25 (Step S46). Alternatively, in Step S46, the processor 11 may create a new characteristic map M1 on the basis of only the voltage range in which the multiple plots have been acquired, and the previous characteristic map M1 before being updated may be continuously used in the other voltage range.

Thereafter, the processor 11 may set the previous update flag at “1” and the previous error flag at “0” (Step S47), and then end the characteristic map creating process. The value of each flag may be continuously used in the next characteristic map creating process.

A program for the characteristic map creating process described above (see FIGS. 6 and 7) may be stored in a non-transitory computer readable medium such as the memory 11a of the processor 11. Alternatively, the processor 11 may read a program from a portable non-transitory computer readable medium and execute the program. The portable non-transitory computer readable medium may store the program for the characteristic map creating process described above.

According to the battery control apparatus 10 of the second example embodiment, the processor 11 may repeat the one-step charging (the process J3 in FIGS. 8 to 10), the suspension of charging and discharging (the process J4 in FIGS. 8 to 10), and the measurement of the characteristic (OCV) of the battery 24 (the process J5 in FIGS. 8 to 10) in the process of charging the battery 24 in the time period T2. Thereafter, the processor 11 may obtain multiple plots from the values of the OCVs measured in the process J5 and the value of SOV which is an integrated value of the amounts of charge in the process J3, and may create the characteristic map M1 on the basis of the multiple plots.

Further, according to the battery control apparatus 10 of the second example embodiment, the processor 11 may change the amount of charge in the one-step charging of the battery 24 in the time period T2 depending on a condition. The step interval within the time period T2 may be varied with the change in the amount of charge. For example, the short step interval st1 (see FIG. 8) may be applied to the charging and discharging process with the first accuracy at Step S28, the long step interval st2 (see FIG. 9) may be applied to the charging and discharging process with the second accuracy at Step S37, and the step intervals st3 and st4 (see FIG. 10), which vary depending on the voltage ranges, may be applied to the charging and discharging process with the changed accuracy at Step S45.

As described above, in a case where the step interval is shortened and where multiple plots are acquired at a short interval, the processing time becomes longer, whereas the characteristic map M1 with high accuracy is created. In contrast, in a case where the step interval is elongated and where plots are acquired at a large interval, the processing time becomes shorter, whereas the accuracy of the created characteristic map M1 decreases. Thus, the processor 11 may vary the step interval in the charging process within the time period T2 on the basis of a condition, which makes it possible to efficiently create the characteristic map M1 appropriate to the condition.

For example, the processor 11 may vary the step interval in the charging process within the time period T2 on the basis of a possible duration time of the charging process. The possible duration time of the charging process may be, for example, a duration time until a departure time set in the timer charging. Such control makes it possible to acquire plots for creating the characteristic map M1 in accordance with a traveling schedule of the electric vehicle 20.

Further, the processor 11 may vary the step interval in the charging process within the time period T2 depending on the voltage ranges on the basis of the error of the characteristic map M1 (e.g., the amount of change of each plot from corresponding one of the plots of the characteristic map M1) in each of the voltage ranges. For example, the processor 11 may apply a short step interval to a voltage range around a plot at which the error is greater than the second threshold, and may apply a long step interval to a voltage range around a plot at which the error is less than or equal to the second threshold (see Step S45 in FIG. 10). Such control makes it possible to create the characteristic map M1 with high accuracy within a voltage range in which the error is large.

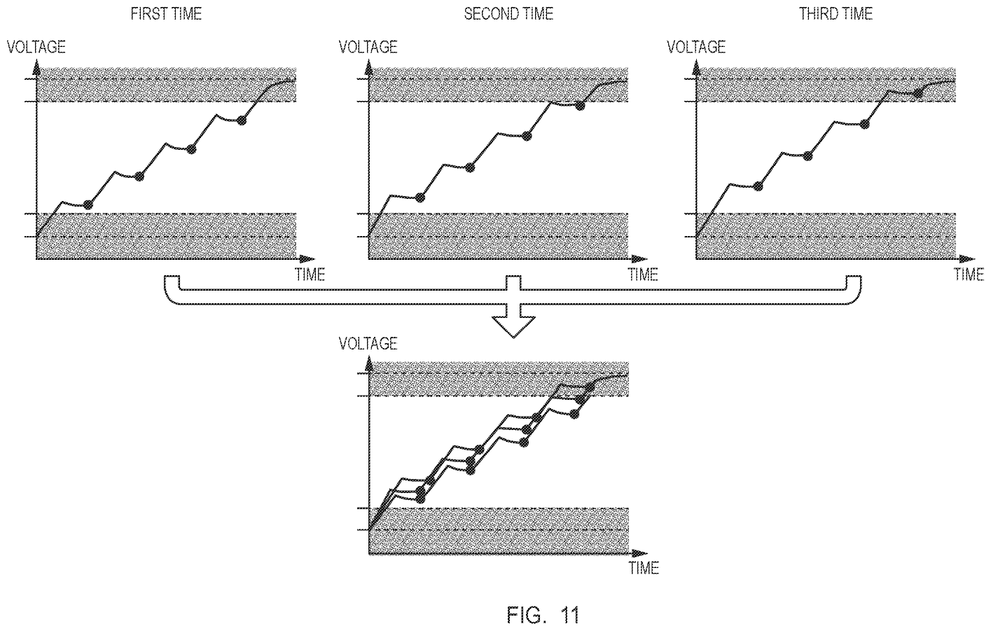

Optionally, the processor 11 may add another process of creating the characteristic map M1 to the control process illustrated in FIGS. 6 and 7. FIGS. 11 to 13 may each illustrate an example of the other process of creating a characteristic map.

For example, in the characteristic map creating process illustrated in FIGS. 6 and 7, the processor 11 may use the plots acquired in the charging and discharging process with the second accuracy (Step S37) to determine whether an error is generated in the current characteristic map M1, rather than to create the characteristic map M1. However, in a case where an error in the current characteristic map M1 is large as a whole, for example, the processor 11 may use the plots acquired in the charging and discharging process with the second accuracy (Step S37) to create a new characteristic map M1 and update the previous characteristic map M1.

In a case where the processor 11 performs the charging and discharging process with the changed accuracy (Step S45), a situation may arise where the processing time obtained as a result of shortening the step interval only in the voltage range in which the characteristic map M1 include a large error is greatly shortened as compared with the time secured for the charging and discharging process. In such a situation, the processor 11 may acquire a large number of plots by shortening the step interval in the other voltage range within the secured time. Using these plots, the processor 11 may update the characteristic map M1 also covering the other voltage range.

Further, in a case where the possible duration time of the charging process is short, the processor 11 may set a long step interval in the charging process within the time period T2, and may slightly shift the timings of the steps from those in the previous charging process (see FIG. 11). Through such a process, the processor 11 may acquire a large number of plots located at a short interval and having discrete OCV values over the multiple charging processes, and may create the characteristic map M1 on the basis of the plots.

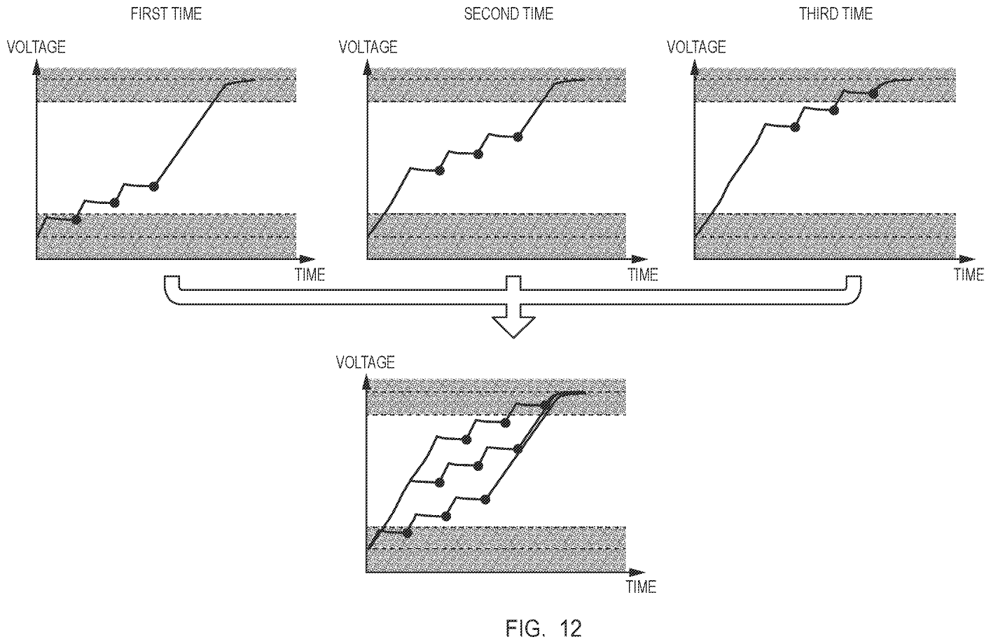

Alternatively, in a case where the possible duration time of the charging process is short, the processor 11 may execute the charging process at a short step interval only in a specific voltage range, and the specific voltage range may differ over the multiple charging processes (see FIG. 12). Through such a process, the processor 11 may acquire a large number of plots located at a short interval and having discrete OCV values over the multiple charging processes, and may create the characteristic map M1 on the basis of these plots.

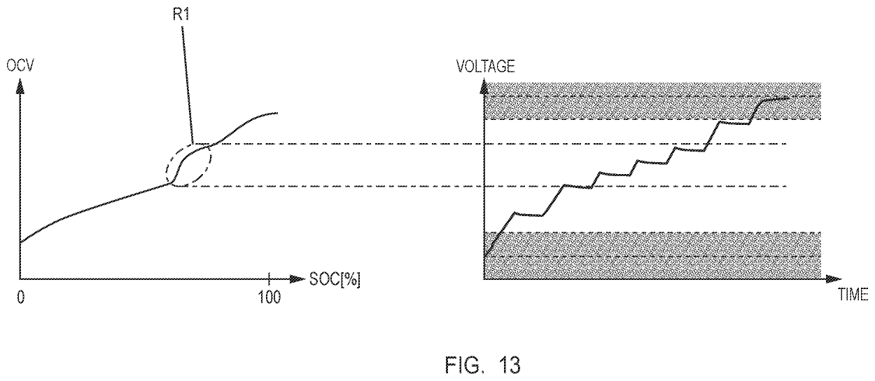

Still alternatively, the processor 11 may search the plots acquired through the charging and discharging process with the second accuracy (Step S37) for a specific region R1 in which the OCV-SOC curve is more difficult to be interpolated than in the other regions. For example, the specific region R1 may be a region having an inflection point or a region having a steep curve with a curvature larger than that in the other region, as illustrated in FIG. 13. Alternatively, the specific region R1 in which the OCV-SOC curve is more difficult to be interpolated than in the other regions may be preliminarily identified by learning. In a case where the possible duration time of the charging process is short, the processor 11 may set a step interval in the charging process so that a larger number of plots are acquired in the specific region R1 than the number of plots acquired in the other regions (see FIG. 13). Thereafter, the processor 11 may create the characteristic map M1 on the basis of the acquired plots. Through such a process, the processor 11 makes it possible to efficiently create the characteristic map M1 with high accuracy.

### Third Example Embodiment

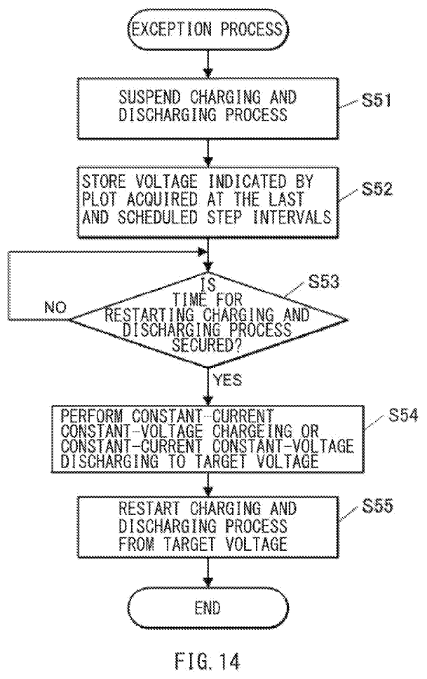

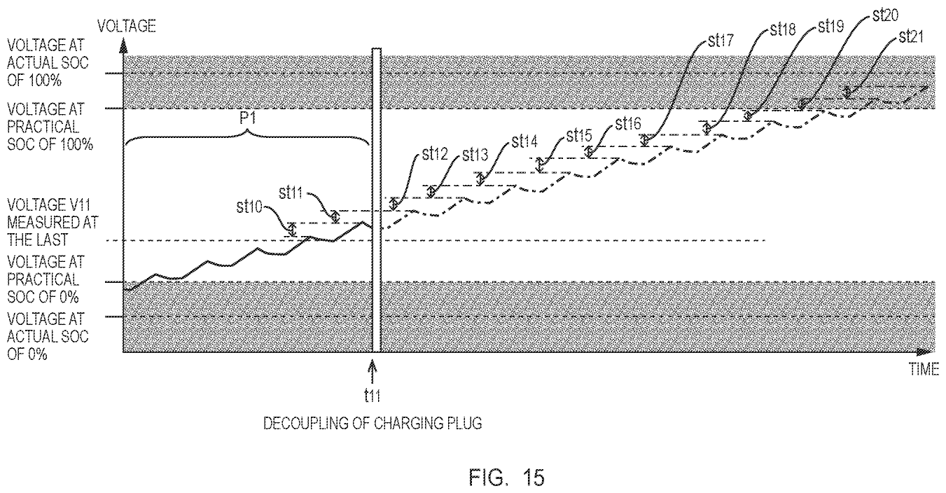

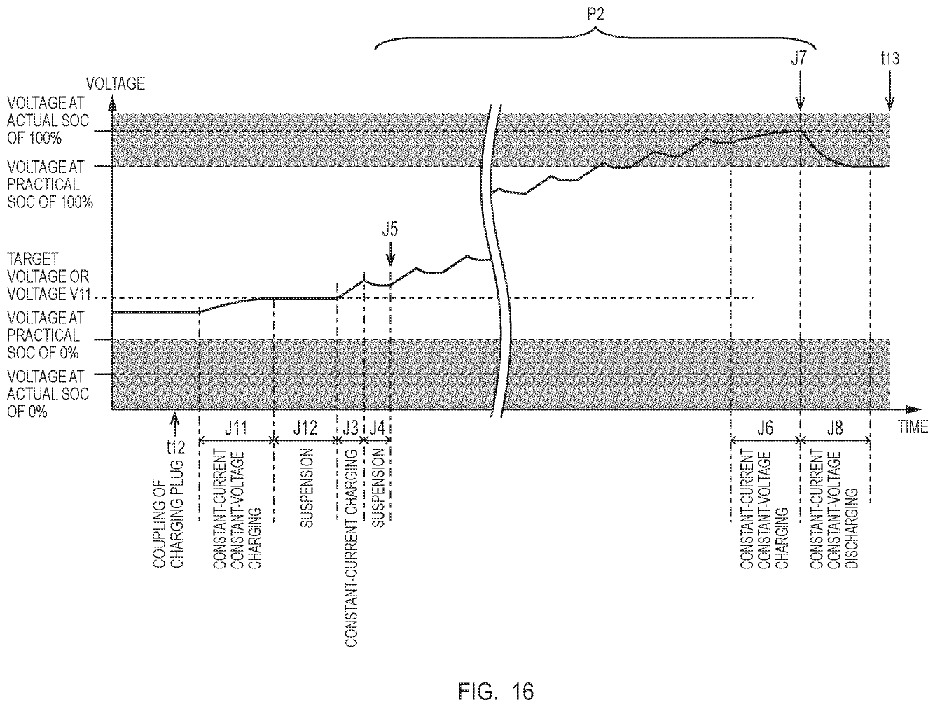

FIG. 14 is a flowchart of an exception process to be performed in a third example embodiment. FIGS. 15 and 16 are timing charts each illustrating an example of a charging and discharging process according to the third example embodiment. FIG. 15 is a timing chart of a part of the charging and discharging process before the exception process, and FIG. 16 is a timing chart of a part of the charging and discharging process after the exception process.

The battery control apparatus 10 of the third example embodiment may be similar to that of the second example embodiment except that the battery control apparatus 10 of the third example embodiment performs the exception process in a case where the process of charging the battery 24 in the time period T2 is unpredictably ended (e.g., in a case where the power transmitter 31 is unintentionally decoupled from the charging equipment 80).

The processor 11 of the battery control apparatus 10 may execute the control process illustrated in FIGS. 6 and 7 as in the second example embodiment. Thereafter, in a case where the power transmitter 31 is decoupled from the charging equipment 80 in the charging process within the time period T2 at any of Steps S28, S37, and S45, the processor 11 may execute the exception process illustrated in FIG. 14. Note that a timing t11 in FIG. 15 indicates decoupling of the charging plug 81.

When the exception process is started, the processor 11 may suspend the charging and discharging process at Step S28, S37, or S45 (Step S51). Thereafter, the processor 11 may store a voltage V11 (see FIG. 15) measured before the decoupling of the power transmitter 31 from the charging equipment 80 and step intervals st 10, st 11, st 12, and subsequent step intervals (see FIG. 15) that have been scheduled (Step S52). The voltage V11 measured immediately before the decoupling may correspond to the voltage (OCV) of a plot acquired at the last.

Thereafter, the processor 11 may wait until a time for restarting the suspended charging and discharging process at Step S28, S37, or S45 is secured (Step S53). In the timing chart illustrated in FIG. 16, it is determined that the time is secured at a timing t12.

If it is determined in Step S53 that the time is secured, the processor 11 may define the voltage V11 measured at the last and stored in Step S52 as a target voltage Vt. Thereafter, the processor 11 may perform constant-current constant-voltage charging or constant-current constant-voltage discharging until the battery 24 reaches the target voltage Vt (see Step S54 and a process J11 in FIG. 16). Thereafter, the processor 11 may suspend charging and discharging to eliminate polarization of the battery 24 (a process J12 in FIG. 16). Note that the target voltage Vt is not limited to the voltage V11 measured at the last and may be a voltage obtained by adding a voltage for the next step interval to the voltage V11.

Thereafter, the processor 11 may restart the charging and discharging process suspended at Step S28, S37, or S45 from the target voltage Vt (Step S55). In FIG. 16, the processes J3 to J8 may be similar to those in the first example embodiment illustrated in FIG. 4. In the timing chart illustrated in FIG. 16, the charging of the battery 24 is completed at the timing t13.

Through the procedure described above, as illustrated in FIGS. 15 and 16, the suspended control process may be restarted on the basis of the plots acquired in a charging process P1 before the decoupling and the plots acquired in a charging process P2 after the suspended charging process is restarted.

A program for the exception process described above with reference to FIG. 14 may be stored in a non-transitory computer readable medium such as the memory 11a of the processor 11. Alternatively, the processor 11 may read a program from a portable non-transitory computer readable medium and execute the program. The portable non-transitory computer readable medium may store the program for the exception process.

According to the battery control apparatus 10 of the third example embodiment described above, in a case where charging of the battery 24 is suspended in the middle of the charging process within the time period T2 for creating the characteristic map M1, the processor 11 may restart the charging process within the time period T2 from a point of the suspension in the next charging and discharging process. Accordingly, even in a case where charging of the battery 24 is unpredictably suspended in the middle of the charging and discharging process for creating the characteristic map M1, it is possible to create the characteristic map M1 in a short time without wasting the plots acquired before the suspension.

### Modification Example of System Configuration

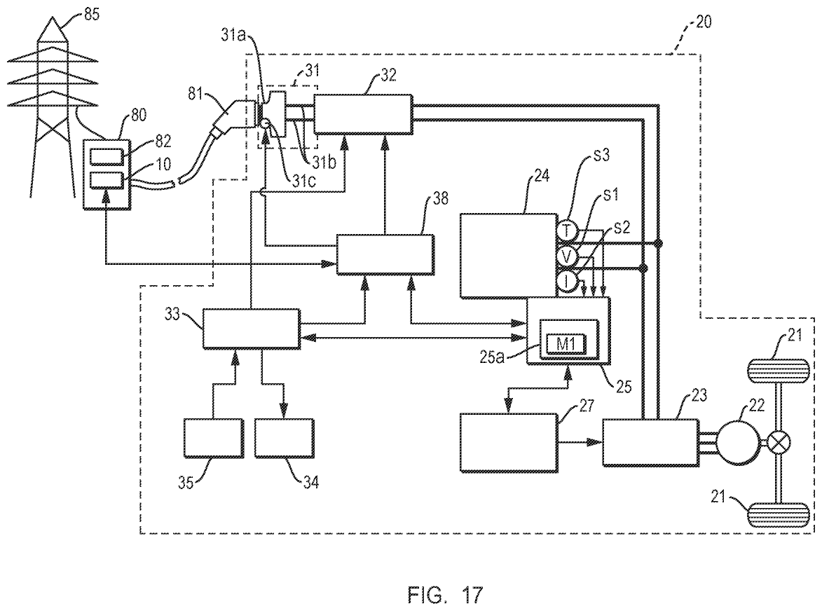

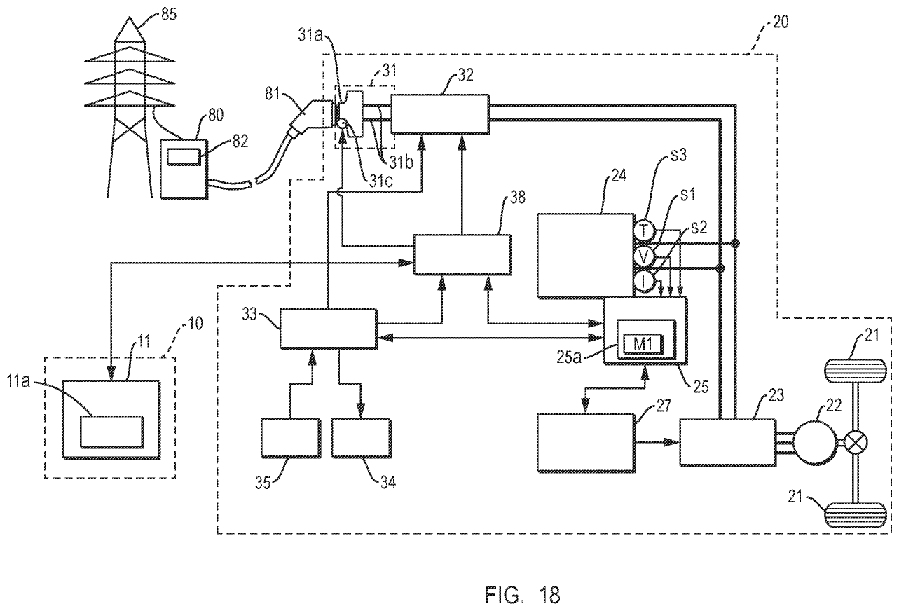

FIG. 17 is a system configuration diagram illustrating another arrangement example of the battery control apparatus according to a modification example. FIG. 18 is a system configuration diagram illustrating still another arrangement example of the battery control apparatus according to a modification example.

In the foregoing example embodiments, the battery control apparatus 10 may be mounted on the electric vehicle 20. However, the battery control apparatus 10 may be provided to the charging equipment 80 as illustrated in FIG. 17. Also in such a case, the processor 11 in the battery control apparatus 10 may communicate with the charging and discharging device 32, the battery control unit 25, and the charging management unit 33 of the electric vehicle 20 via, for example, the communicator 38 to thereby control the charging and discharging operation of the charging management unit 33. As a result, it is possible to achieve processes similar to those in the foregoing example embodiments.

As illustrated in FIG. 18, the battery control apparatus 10 may be a portable device to be carried by the user or a maintenance personnel. When the battery 24 of the electric vehicle 20 is charged by the charging equipment 80, the processor 11 may be coupled to the charging and discharging device 32, the battery control unit 25, and the charging management unit 33 of the electric vehicle 20 via, for example, the communicator 38 before use. Also with such a configuration, it is possible to achieve processes similar to those in the foregoing example embodiment.

Some example embodiments of the disclosure are described above. However, example embodiments of the disclosure are not limited the above-described embodiments. For example, the processor 11 of the battery control apparatus 10 may be incorporated into the battery control unit 25. That is, the battery control unit 25 may serve as the processor 11 of the battery control apparatus 10. Alternatively, the processor 11 of the battery control apparatus 10 may be incorporated into the vehicle control unit 27 or the charging management unit 33. That is, the vehicle control unit 27 or the charging management unit 33 may serve as the processor 11 of the battery control apparatus 10. Further, in the foregoing example embodiments, the OCV may be employed as a component of the characteristic map. However, a voltage of the battery, which is not regarded as an OCV in a precise sense, may be employed as a component of the characteristic map. The other details described in the foregoing example embodiments may be modified as needed without departing from the gist of the disclosure.

According to the foregoing example embodiments of the disclosure, the processor causes the battery to discharge to the charging equipment once before the battery is charged. This allows charging of the battery to start from a voltage less than or equal to the discharge end voltage. While the battery is charged to a voltage greater than or equal to the charge end voltage, the processor may measure the amount of charge and the voltage of the battery within a range from the discharge end voltage to the charge end voltage. On the basis of the results of the measurement, the processor creates an accurate characteristic map indicating the relation between the SOC and the voltage of the battery. Further, the electric power discharged from the battery at the time of discharging to the discharge end voltage may be received by the charging equipment. This prevents discharged electric power from being wasted without contradicting eco-friendly, energy-saving guidelines. Further, unlike in the case of waste discharging, it is possible to reduce a loss for the user. Accordingly, even in a case where electric power remains in the battery, it is possible to create an accurate characteristic map while reducing a loss for the user without contradicting energy-saving guidelines.

1. A battery control apparatus for an electric vehicle, the battery control apparatus comprising
a processor configured to
control a charging and discharging device of the electric vehicle, the electric vehicle comprising a battery configured to store electric power for traveling, a power transmitter configured to perform electric power transmission between the power transmitter and charging equipment provided outside the electric vehicle, and the charging and discharging device configured to charge and discharge the battery via the power transmitter,
cause the battery to discharge to the charging equipment via the power transmitter until a voltage of the battery reaches a discharge end voltage corresponding to a state of charge of 0%, and thereafter cause the battery to be charged until the voltage of the battery reaches a charge end voltage corresponding to the state of charge of 100%, and
create a characteristic map representing a relation between the state of charge of the battery and the voltage of the battery.

2. The battery control apparatus according to claim 1, wherein
a practical state of charge and an actual state of charge are each defined as the state of charge of the battery, the practical state of charge being configured to be displayed to an occupant of the electric vehicle, the actual state of charge being configured to be used to measure a characteristic of the battery,
the processor is further configured to employ the actual state of charge as the state of charge to be used to create the characteristic map, and
a voltage of the battery at the actual state of charge of 100% is greater than a voltage of the battery at the practical state of charge of 100%.

3. The battery control apparatus according to claim 2, wherein a voltage of the battery at the actual state of charge of 0% is less than a voltage of the battery at the practical state of charge of 0%.

4. The battery control apparatus according to claim 2, wherein
the processor is further configured to cause the battery to be charged until the voltage of the battery reaches the voltage at the actual state of charge of 100%, and thereafter cause the battery to discharge to the charging equipment until the voltage of the battery reaches the voltage at the practical state of charge of 100%.

5. The battery control apparatus according to claim 3, wherein
the processor is further configured to cause the battery to be charged until the voltage of the battery reaches the voltage at the actual state of charge of 100%, and thereafter cause the battery to discharge to the charging equipment until the voltage of the battery reaches the voltage at the practical state of charge of 100%.

6. The battery control apparatus according to claim 2, wherein the processor is configured to prevent the power transmitter from decoupling from the charging equipment in a case where the voltage of the battery is greater than the voltage of the battery at the practical state of charge of 100% or in a case where the voltage of the battery is less than a voltage of the battery at the practical state of charge of 0%.

7. The battery control apparatus according to claim 3, wherein the processor is configured to prevent the power transmitter from decoupling from the charging equipment in a case where the voltage of the battery is greater than the voltage of the battery at the practical state of charge of 100% or in a case where the voltage of the battery is less than the voltage of the battery at the practical state of charge of 0%.

8. The battery control apparatus according to claim 4, wherein the processor is configured to prevent the power transmitter from decoupling from the charging equipment in a case where the voltage of the battery is greater than the voltage of the battery at the practical state of charge of 100% or in a case where the voltage of the battery is less than a voltage of the battery at the practical state of charge of 0%.

9. The battery control apparatus according to claim 5, wherein the processor is configured to prevent the power transmitter from decoupling from the charging equipment in a case where the voltage of the battery is greater than the voltage of the battery at the practical state of charge of 100% or in a case where the voltage of the battery is less than the voltage of the battery at the practical state of charge of 0%.
